(19) United States
(12) Patent Application Publication
(10) Pub. No.: US 2016/0126259 A1
(43) Pub. Date: May 5, 2016

(54) ARRAY SUBSTRATE AND METHOD OF PRODUCING THE SAME, DISPLAY PANEL AND DISPLAY DEVICE

(71) Applicants: BOE Technology Group Co., Ltd., Beijing (CN); Beijing BOE Display Technology Co., Ltd., Beijing (CN)

(72) Inventors: Kwon Namin, Beijing (CN); Cheong Yo Seop, Beijing (CN); Yi Ouyang, Beijing (CN); Lina Wang, Beijing (CN)

(21) Appl. No.: 14/802,311

(22) Filed: Jul. 17, 2015

(30) Foreign Application Priority Data
Oct. 31, 2014 (CN) 201410602735.1

(51) Int. Cl. H01L 27/12; G02F 1/1362; G02F 1/1333; G02F 1/1368

(52) U.S. Cl. CPC H01L 27/124; H01L 27/1262; G02F 1/1368; G02F 1/136286; G02F 1/133345; G02F 2001/136295

(57) ABSTRACT

Embodiments of the present invention provide an array substrate and a method of producing the same, a display panel and a display device, solving problems of detaching of film formed by CVD in the array substrate in prior art. The array substrate includes a plurality of data lines and a plurality of gate lines that are disposed in cross orientation. The array substrate further includes: a conductive repairing structure located at a damaged region of the data line and/or a damaged region of the gate line; and an insulating protective film configured to cover a region where at least one conductive repairing structure is located. As the region where the at least one conductive repairing structure is located is covered by the insulating protective film, the conductive repairing structure covered by the insulating protective film is not prone to be detached off.

### CROSS-REFERENCE TO RELATED APPLICATIONS

This application claims the benefit of Chinese patent application No. 201410602735.1, filed on Oct. 31, 2014 with State Intellectual Property Office of China, and the disclosures of which are incorporated herein in its entirety by reference.

### BACKGROUND

1. Field of the Disclosure

The present disclosure relates to display field, and particularly to an array substrate and a method of producing the same, a display panel and a display device.

2. Description of the Related Art

Thin Film Transistor Liquid Crystal Display (T-LCD) has advantages of small volume, low power consumption and non-radiation, etc. and thus possesses predominant status in current panel display device market and is widely used in notebook computer, personal digital assistant (PDA), mobile phone, television, monitor, etc. As for a TFT-LCD product, its performance, yield and price are determined by the structure of the array substrate and the producing process thereof.

During producing a TFT-LCD display panel, an arraying process of the array substrate would cause open circuit defects in a data line and/or a gate line in the array substrate for various factors (for example, over etching, or particles contained). A cell cutting process for the array substrate would also result in scraping defects in lead region of the panel, thereby causing open circuit defects in the lead portion of the data line or the gate line.

In prior art, in order to repair the open circuit defects in the display panel, it is known to plate a layer of tungsten film on the position where open circuit defects occur in the array substrate by means of Chemical Vapor Deposition (CVD). However, the film formed by way of CVD is prone to detach from the array substrate during subsequent processes, such as rinsing and washing process etc. Thus, the resulted array substrate still involves risk of inclusion of open circuit defects.

### SUMMARY OF THE DISCLOSURE

According to an embodiment of the present disclosure, there is provided an array substrate and a method of producing the same, a display panel and a display device, so as to solve the problem in the prior art that a film formed by way of CVD is prone to detach off or lift off.

According to an embodiment of the present disclosure, there is provided an array substrate, comprising a plurality of data lines and a plurality of gate lines that are disposed in cross orientation, wherein, the array substrate further comprising:

a conductive repairing structure located at a damaged region of the data line and/or a damaged region of the gate line; and an insulating protective film configured to cover a region where the at least one conductive repairing structure is located.

In an example, the region where each of the at least one conductive repairing structure is located is covered by the insulating protective film.

In an example, the insulating protective film is made by a transparent material.

In an example, the insulating protective film is made by an acrylic fibre resin material.

According to an embodiment of the present disclosure, there is provided a display panel, comprising the array substrate according to any of the above embodiments.

According to an embodiment of the present disclosure, there is provided a display device, wherein the display panel comprises the array substrate according to any of the above embodiments.

According to an embodiment of the present disclosure, there is provided a method of producing an array substrate, wherein, after forming a gate line and a data line on the substrate, the method further comprises:

if the gate line has a damaged region, forming a conductive repairing structure at the damaged region of the gate line; and, if the data line has a damaged region, forming a conductive repairing structure at the damaged region of the data line; and/or

coating an insulation material on a region where at least one conductive repairing structure is located so as to form an insulating protective film on the at least one conductive repairing structure.

In an example, the step of coating an insulation material on the region where at least one conductive repairing structure is located so as to form the insulating protective film on the at least one conductive repairing structure comprises:

coating acrylic fibre liquid at the region where the at least one conductive repairing structure is located; and

performing a curing treatment on the acrylic fibre liquid to form the insulating protective film on the at least one conductive repairing structure.

In an example, the step of performing a curing treatment on the acrylic fibre liquid comprises:

performing the curing treatment on the acrylic fibre liquid through an ultraviolet light curing approach; or

performing the curing treatment on the acrylic fibre liquid through a heating approach.

In an example, the step of coating an insulation material on the region where at least one conductive repairing structure is located so as to form the insulating protective film on the at least one conductive repairing structure comprises:

coating an insulation material on each of the conductive repairing structures so as to form the insulating protective film on the each of the conductive repairing structures.

The array substrate and the method of producing the same, the display panel and the display device according to embodiments of the present disclosure are designed to provide an insulating protective film covering the region where the at least one conductive repairing structure is located, so as to prevent the conductive repairing structure covered by the insulating protective film from being lifted off.

### BRIEF DESCRIPTION OF THE DRAWINGS

FIG. 1 is a schematic structural view of an array substrate according to an embodiment of the present disclosure;

FIG. 2 is a schematic flow chart of a method of producing an array substrate according to an embodiment of the present invention;

FIG. 3A-3C are schematic views of the structures formed during producing the array substrates shown in FIG. 2.

### DETAILED DESCRIPTION OF THE PREFERRED EMBODIMENTS

Technical solutions of the present disclosure will be described explicitly and fully hereinafter in detail by the way of embodiments with reference to the accompanying drawings. Obviously, the described embodiments are only some of embodiments of the present disclosure, rather than all the embodiments. Other embodiments obtained without involving inventive labors by those skilled in the art based on the described embodiments of the present disclosure will fall within the scope of the present disclosure.

In addition, in the following description, details of embodiments are expounded concretely for explanation. However, it is noted that one or more embodiments may be implemented without explanations in details by those skilled in the art. In any other case, the known structures and devices are shown schematically to simplify the accompanying drawings.

An embodiment of the present invention is designed to provide an insulating protective film at a region where at least one conductive repairing structure is located so as to cover the at least one conductive repairing structure by the insulating protective film, thereby prevent the conductive repairing structure protected by the insulating protective film from being lifted off.

Embodiments of the present disclosure will be described with reference to the accomplish drawing. It is appreciated that the embodiments illustrated herein are provided only for illustrating and interpreting the present invention, but not to limit the present invention.

According to an embodiment of the present disclosure, there is provided an array substrate, comprising a plurality of data lines and a plurality of gate lines that are disposed in cross orientations, wherein, the array substrate further comprising:

a conductive repairing structure located at a damaged region of the data line and/or a damaged region of the gate line; and

an insulating protective film configured to cover a region where the at least one conductive repairing structure is located.

According to an embodiment, the array substrate is designed to provide an insulating protective film covering the region where the at least one conductive repairing structure is located, so as to prevent the conductive repairing structure covered by the insulating protective film from being detached off.

In the array substrate according to the embodiment of the present disclosure, the damaged region of the data line, i.e., the portion of the data line including an open circuit defect, includes a broken portion in the data line (i.e., the damaged portion of the data line due to over etching and the like) and a detached portion at edge of the data line (i.e., the portion at edge of the data line is detached due to cutting process). Similarly, the damaged region of the gate line, i.e., the portion of the gate line including an open circuit defect, includes a broken portion in the gate line (i.e., the damaged portion of the gate line due to over etching and the like) and a detached portion at edge of the gate line (i.e., the portion at edge of the gate line is detached due to cutting process).

In the array substrate according to the embodiment of the present disclosure, the conductive repairing structure disposed on the damaged region of the data line for repairing the damaged region of the data line to ensure electrically connection performance of the data line. Further, the conductive repairing structure disposed on the damaged region of the gate line for repairing the damaged region of the gate line to ensure electrical connection performance of the gate line.

In the array substrate according to the embodiment of the present disclosure, the insulating protective film covering the region where the conductive repairing structure is located completely encloses the conductive repairing structure, such that the conductive repairing structure covered by the insulating protective film is not prone to be detached from the array substrate due to bonding action between the insulating protective film and other structure (such as a passivation layer) under the conductive repairing structure. The insulating protective film imposes protection to the conductive repairing structure.

In order to ensure electrical connection performance of each gate line and each data line in the array substrate, it is required that each conductive repairing structure is free of separation. As an example, the region where each of the at least one conductive repairing structure is located is covered by an insulating protective film.

As an example, the insulating protective film is made by transparent material in order to avoid influence of the insulating protective film on light transmission of the structures below the insulating protective film.

As an example, the insulating protective film is made by an acrylic fibre resin material. However, it is noted that the insulating protective film according to embodiments of the present disclosure may be made by other material other than the acrylic fibre resin, provided that the material has properties of such as electrical isolation, transparency, and good adhesion.

According to an embodiment of the present disclosure, as the acrylic fibre resin material is in liquid phase, it is easy to control a thickness of the insulating protective film such that the insulating protective film will not affect subsequent processes, thereby improving flatness of the array substrate.

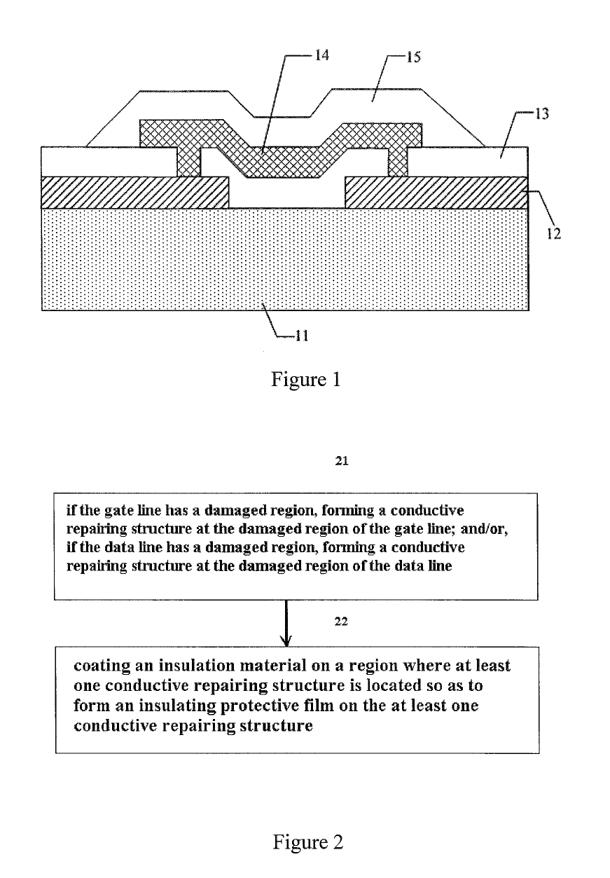

The structure of the array substrate according to an embodiment of the present disclosure will be described with reference to an example of fabrication of an insulating protective film covering a conductive repairing structure in a damaged region of the gate line. As shown in FIG. 1, a gate line 12 is formed on a substrate 11 and a passivation layer 13 is formed on the gate line 12. Due to over etching, a broken region appears in the gate line 12. In order to ensure electrical connection performance of the gate line 12, a layer of conductive repairing structure 14 is formed on the gate line 12 by way of CVD to achieve electrical connection of the gate line 12 at the broken region. As the conductive repairing structure 14 is prone to be detached off, there is provided an insulating protective film 15 in the embodiment of the present disclosure to cover the conductive repairing structure 14 such that the conductive repairing structure 14 is free of separation by the bonding action between the insulating protective film 15 and the passivation layer 13.

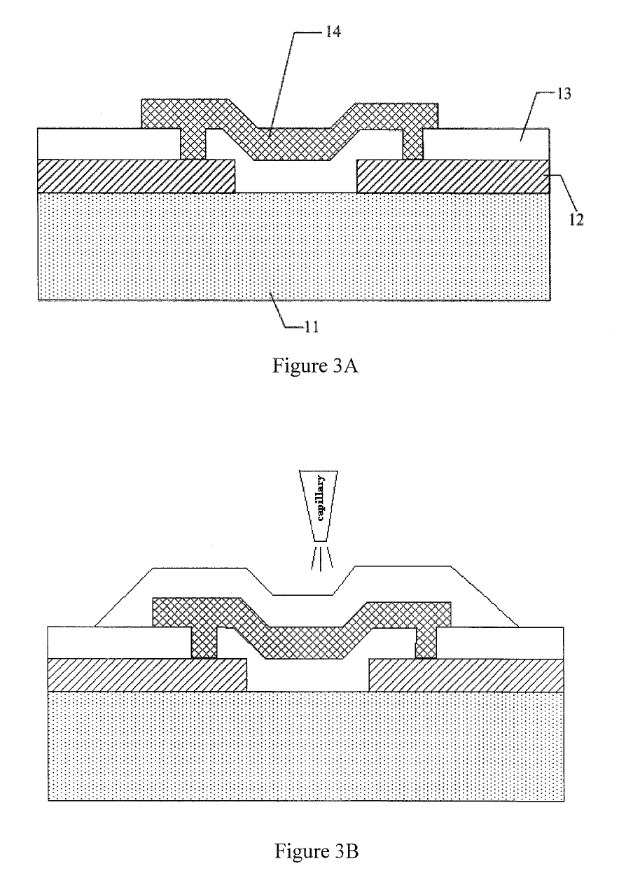

There is provided a method of producing an array substrate according to an embodiment of the present disclosure, as shown in FIG. 2, wherein, after forming a gate line and a data line on the substrate, the method further comprises:

Step 21: if the gate line has a damaged region, forming a conductive repairing structure at the damaged region of the gate line; and/or, if the data line has a damaged region, forming a conductive repairing structure at the damaged region of the data line;

Step 22: coating an insulation material on a region where at least one conductive repairing structure is located so as to form an insulating protective film on the at least one conductive repairing structure.

in an example, in step 22, the step of coating an insulation material on the region where at least one conductive repairing structure is located so as to form the insulating protective film on the at least one conductive repairing structure comprises:

coating acrylic fibre liquid at the region where the at least one conductive repairing structure is located; and

performing a curing treatment on the acrylic fibre liquid to form the insulating protective film covering the region where the at least one conductive repairing structure is located.

In an example, in order to ensure a sufficient thickness of the coated acrylic fibre liquid, the acrylic fibre liquid may be injected into a capillary and discharge of the acrylic fibre liquid may be controlled by controlling a pressure in the capillary, which, in turn, controls size and thickness of the coating area of the acrylic fibre liquid.

In an example, the step of performing a curing treatment on the acrylic fibre liquid comprises:

performing the curing treatment on the acrylic fibre liquid through an ultraviolet light curing approach; or

performing the curing treatment on the acrylic fibre liquid through a heating approach.

According to any of the above embodiments, in the step 22, the step of coating an insulation material on the region where at least one conductive repairing structure is located so as to form the insulating protective film on the at least one conductive repairing structure comprises:

coating an insulation material on the region where each of the at least one conductive repairing structure is located so as to form the insulating protective film covering on the each of the at least one conductive repairing structure.

With reference to the structure shown in FIG. 1, a method of producing an array substrate according to an embodiment of the present disclosure is described in detailed. The method includes the following process.

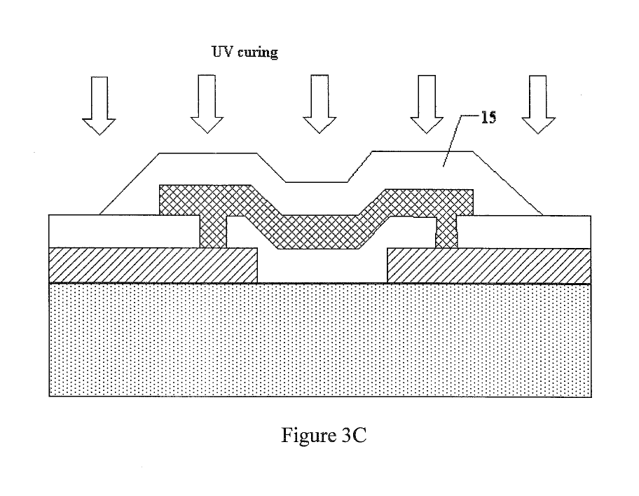

Firstly, a metal film is plated on an array substrate, on which a gate line 12 and a passivation layer 13 have been formed, by way of CVD so as to form a conductive repairing structure 14 at a broken region of the gate line 12, as shown in FIG. 3A;

Then, an acrylic fibre resin liquid is coated on the conductive repairing structure 14 by a capillary filled with the acrylic fibre resin liquid, as shown in FIG. 3B;

Finally, the acrylic fibre resin liquid is cured by ultraviolet light to form an insulating protective film 15, as shown in FIG. 3C. By this approach, stability of the insulating protective film 15 may be ensured.

Based on the same inventive concept, there is provided a display panel according to an embodiment of the present disclosure, wherein the display panel includes the array substrate according to the above embodiments.

Based on the same inventive concept, there is provided a display device according to an embodiment of the present disclosure, wherein the display device includes the array substrate according to the above embodiments.

The display device according to embodiments of the present disclosure may be any products or components having display functions, for example, a liquid crystal display panel, an electronic paper, an organic light emitting diode (OLED) panel, a mobile phone, a tablet computer, a television, a display, a notebook computer, a digital photo frame or a navigator.

Although several embodiments of the general inventive concept are illustrated and explained, it would be appreciated by those skilled in the art that modifications and variations can be made in these embodiments without departing from the principles and spirit of the general inventive concept of the disclosure, the scope of which is defined in the appended claims and their equivalents.

Any changes, equivalent replacement, modification within the spirit and principles of the disclosure that can be made by those skilled in the art and should fall within the scope of the disclosure, if these changes and modifications belong to scope of the appended claims and their equivalents.

1. An array substrate, comprising a plurality of data lines and a plurality of gate lines that are disposed in cross orientation, the array substrate further comprising:
a conductive repairing structure located at a damaged region of the data line and/or a damaged region of the gate line; and
an insulating protective film configured to cover a region where the at least one conductive repairing structure is located.

2. The array substrate according to claim 1, wherein, the region where each of the at least one conductive repairing structure is located is covered by the insulating protective film.

3. The array substrate according to claim 1, wherein, the insulating protective film is made by a transparent material.

4. The array substrate according to claim 1, wherein, the insulating protective film is made by an acrylic fibre resin material.

5. The array substrate according to claim 2, wherein, the insulating protective film is made by an acrylic fibre resin material.

6. The array substrate according to claim 3, wherein, the insulating protective film is made by an acrylic fibre resin material.

7. A display panel, comprising the array substrate according to claim 1.

8. The display panel according to claim 7, wherein, the region where each of the at least one conductive repairing structure is located is covered by the insulating protective film.

9. The display panel according to claim 7, wherein, the insulating protective film is made by a transparent material.

10. The display panel according to claim 7, wherein, the insulating protective film is made by an acrylic fibre resin material.

11. A display device, comprising the array substrate according to claim 1.

12. A method of producing an array substrate, wherein, after forming a gate line and a data line on the substrate, the method further comprises:
if the gate line has a damaged region, forming a conductive repairing structure at the damaged region of the gate line; and, if the data line has a damaged region, forming a conductive repairing structure at the damaged region of the data line; and/or
coating an insulation material on a region where at least one conductive repairing structure is located so as to form an insulating protective film on the at least one conductive repairing structure.

13. The method according to claim 12, wherein, the step of coating an insulation material on the region where at least one conductive repairing structure is located so as to form the insulating protective film on the at least one conductive repairing structure comprises:
coating acrylic fibre liquid at the region where the at least one conductive repairing structure is located; and
performing a curing treatment on the acrylic fibre liquid to form the insulating protective film on the at least one conductive repairing structure.

14. The method according to claim 13, wherein, the step of performing a curing treatment on the acrylic fibre liquid comprises:
performing the curing treatment on the acrylic fibre liquid through an ultraviolet light curing approach; or
performing the curing treatment on the acrylic fibre liquid through a heating approach.

15. The method according to claim 12, wherein, the step of coating an insulation material on the region where at least one conductive repairing structure is located so as to form the insulating protective film on the at least one conductive repairing structure comprises:
coating an insulation material on the region where each of the at least one conductive repairing structure is located so as to form the insulating protective film on the each of the at least one conductive repairing structure.

16. The method according to claim 13, wherein, the step of coating an insulation material on the region where at least one conductive repairing structure is located so as to form the insulating protective film on the at least one conductive repairing structure comprises:
coating an insulation material on the region where each of the at least one conductive repairing structure is located so as to form the insulating protective film on the each of the at least one conductive repairing structure.

17. The method according to claim 14, wherein, the step of coating an insulation material on the region where at least one conductive repairing structure is located so as to form the insulating protective film on the at least one conductive repairing structure comprises:
coating an insulation material on each of the at least one conductive repairing structure so as to form the insulating protective film on the each of the at least one conductive repairing structure.
